(19) United States
(12) Patent Application Publication
(10) Pub. No.: US 2026/0073921 A1
(43) Pub. Date: Mar. 12, 2026

(54) SEMICONDUCTOR MANUFACTURING APPARATUS AND SUPPORT METHOD

(71) Applicant: Tokyo Electron Limited, Tokyo (JP)

(72) Inventor: Hisaaki KATAYAMA, Hokkaido (JP)

(21) Appl. No.: 19/315,726

(22) Filed: Sep. 1, 2025

(30) Foreign Application Priority Data
Sep. 6, 2024 (JP) 2024-153615

(51) Int. Cl. G10L 15/26; G10L 15/22; H01L 21/67

(52) U.S. Cl. CPC G10L 15/26; G10L 15/22; H10P 72/0612

(57) ABSTRACT

A semiconductor manufacturing apparatus includes a recording unit that records content spoken by a first worker, a speech-to-text conversion unit that converts the content recorded by the recording unit, into text, and a display control unit that causes the text to be displayed on a display device viewable by a second worker.

### CROSS REFERENCES TO RELATED APPLICATIONS

This application is based on and claims priority from Japanese Patent Application No. 2024-153615, filed on Sep. 6, 2024, with the Japan Patent Office, the disclosure of which is incorporated herein in its entirety by reference.

### TECHNICAL FIELD

The present disclosure relates to a semiconductor manufacturing apparatus and a support method.

### BACKGROUND

Japanese Patent Laid-Open Publication No. 2024-024393 discloses, for example, a technique for appropriately supporting work performed on inspection equipment, manufacturing equipment, and similar equipment.

### SUMMARY

According to an aspect of the present disclosure, a semiconductor manufacturing apparatus includes a recording unit that records content spoken by a first worker, a speech-to-text conversion unit that converts the recorded content into text, and a display control unit that causes the text to be displayed on a display device viewable by a second worker.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating an example of the overview of a semiconductor manufacturing apparatus and a support method according to the present embodiment.

FIG. 2 is a configuration diagram illustrating an example of a support system according to the present embodiment.

FIG. 3 is a diagram illustrating an example hardware configuration of a computer.

FIG. 4 is a functional block diagram illustrating an example of the semiconductor manufacturing apparatus according to the present embodiment.

FIG. 5 is a sequence diagram illustrating an example of processing performed by the semiconductor manufacturing apparatus according to the present embodiment.

FIG. 6 is a configuration diagram illustrating an example of a support system according to the present embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, the present embodiment will be described with reference to the drawings.

### Overview

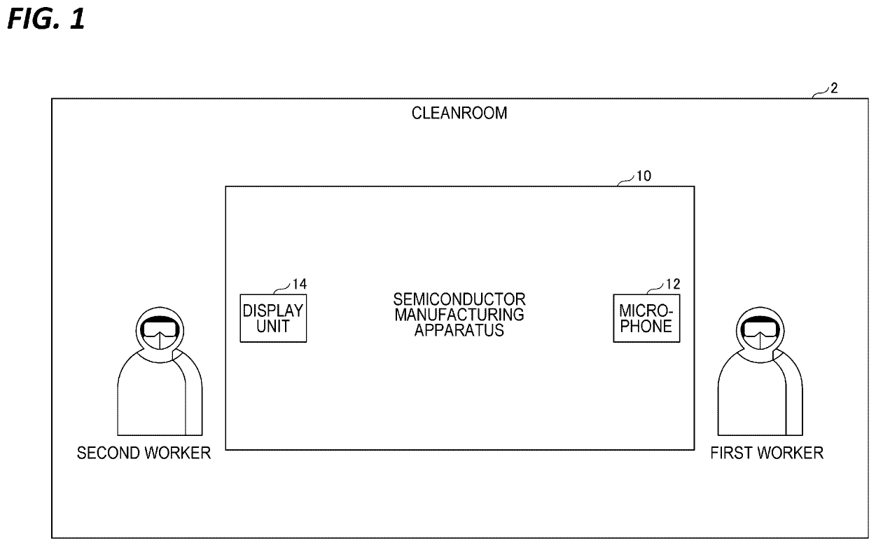

FIG. 1 is a diagram illustrating an example of the overview of a semiconductor manufacturing apparatus 10 and a support method according to the present embodiment. The semiconductor manufacturing apparatus 10 is an example of an apparatus on which work is performed by a first worker and a second worker. The semiconductor manufacturing apparatus 10 performs a processing such as film formation, etching, or ashing, and processes a substrate such as, for example, a wafer W. Examples of the semiconductor manufacturing apparatus 10 include a substrate processing apparatus, a thermal processing apparatus, and a film forming apparatus.

One or more semiconductor manufacturing apparatuses 10 are arranged inside a cleanroom 2 where air cleanliness is maintained. Therefore, the first and second workers who perform work on the semiconductor manufacturing apparatus 10 wear cleanroom suits and perform their work inside the cleanroom 2. The first and second workers wear cleanroom suits that cover their ears. The cleanroom suit refers to a dust-proof full-body garment worn by workers when performing work inside the cleanroom 2.

Further, the cleanroom 2 is a noisy environment with high ambient noise levels. Accordingly, the first and second workers who work on the semiconductor manufacturing apparatus 10 are in a situation where it is difficult to hear sounds. Due to this difficulty in hearing, when the first and second workers inside the cleanroom 2 try to communicate verbally, mutual understanding may not be achieved. When communication fails, operational mistakes or accidents may occur due to insufficient communication.

In view of this, the present embodiment supports communication between the first and second workers who perform work on the semiconductor manufacturing apparatus 10 as described below. Here, an example will be described in which the first worker sends a message to the second worker.

The semiconductor manufacturing apparatus 10 is equipped with a microphone 12 and a display unit 14. The microphone 12 and the display unit 14 may be built into or externally attached to the semiconductor manufacturing apparatus 10. The first worker speaks the content intended for the second worker. The microphone 12 outputs an audio signal of the first worker's speech to the semiconductor manufacturing apparatus 10.

The semiconductor manufacturing apparatus 10 records the content spoken by the first worker, converts the recorded data into text as described later, and displays the text on the display unit 14, which is an example of a display device viewable by the second worker. The second worker may accurately understand the content spoken by the first worker through the text displayed on the display unit 14. In this way, the present embodiment enables smooth communication between the first and second workers, thereby reducing the occurrence of operational mistakes or accidents due to insufficient communication.

### <System Configuration>

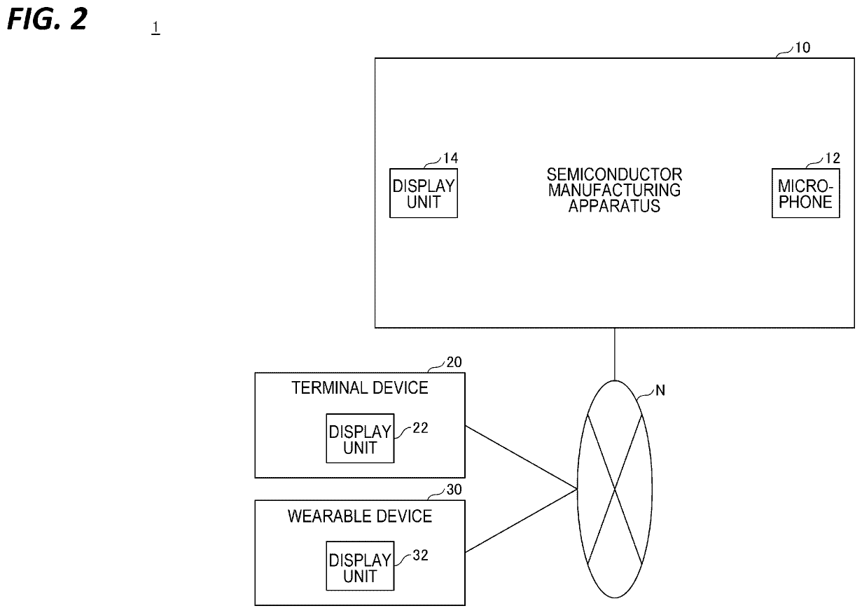

FIG. 2 is a configuration diagram illustrating an example of a support system 1 according to the present embodiment. The support system 1 illustrated in FIG. 2 includes the semiconductor manufacturing apparatus 10, a terminal device 20, and a wearable device 30. The terminal device 20 is an information processing terminal such as a personal computer (PC) or smartphone possessed by the second worker. The wearable device 30 is, for example, a head-mounted display (HMD) worn by the second worker.

The semiconductor manufacturing apparatus 10, the terminal device 20, and the wearable device 30 are connected to enable data communication via a network N such as the Internet or a local area network (LAN).

The terminal device 20 includes a display unit 22. Further, the wearable device 30 includes a display unit 32. The display unit 14 of the semiconductor manufacturing apparatus 10, the display unit 22 of the terminal device 20, and the display unit 32 of the wearable device 30 are examples of a display device viewable by the second worker.

The support system 1 illustrated in FIG. 2 is merely an example, and various system configuration examples may be employed depending on the intended use or purpose. At least one of the display unit 14 of the semiconductor manufacturing apparatus 10, the display unit 22 of the terminal device 20, and the display unit 32 of the wearable device 30 may be used as a display device viewable by the second worker.

### <Hardware Configuration>

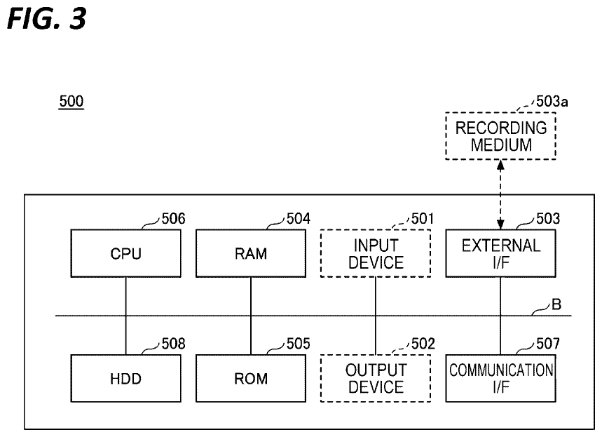

The terminal device 20 and the wearable device 30 illustrated in FIG. 2 may be implemented using, for example, a computer with a hardware configuration illustrated in FIG. 3. Further, an apparatus controller 16 of the semiconductor manufacturing apparatus 10, which will be described later, may also be implemented using, for example, the computer with the hardware configuration illustrated in FIG. 3. FIG. 3 is a diagram illustrating an example of a hardware configuration of a computer 500.

The computer 500 illustrated in FIG. 3 includes an input device 501, an output device 502, an external interface (I/F) 503, a random access memory (RAM) 504, a read only memory (ROM) 505, a central processing unit (CPU) 506, a communication I/F 507, and a hard disk drive (HDD) 508, among others, and these components are interconnected via a bus B. The input device 501 and the output device 502 may be configured to be connected and used as needed.

The input device 501 may be, for example, a keyboard, mouse, or touch panel, and is used by by a worker or other user to input operation signals. The output device 502 may be, for example, a display, and is used to display the results of processing by the computer 500. The communication I/F 507 is an interface that connects the computer 500 to the networks N illustrated in FIG. 2. The HDD 508 is an example of a non-volatile storage device that stores programs and data.

The external I/F 503 is an interface for an external device. The computer 500 may read information from a recording medium 503a such as a secure digital (SD) memory card via the external I/F 503. The external I/F 503 may also write information to the recording medium 503a such as an SD memory card via the external I/F 503.

The ROM 505 is an example of a non-volatile semiconductor memory (storage device) that stores programs and data. The RAM 504 is an example of a volatile semiconductor memory (storage device) that temporarily holds programs and data. The CPU 506 is a processing unit that reads programs and data from a storage device such as the ROM 505 or the HDD 508 and loads them into the RAM 504, and executes processing to control and implement the overall functions of the computer 500.

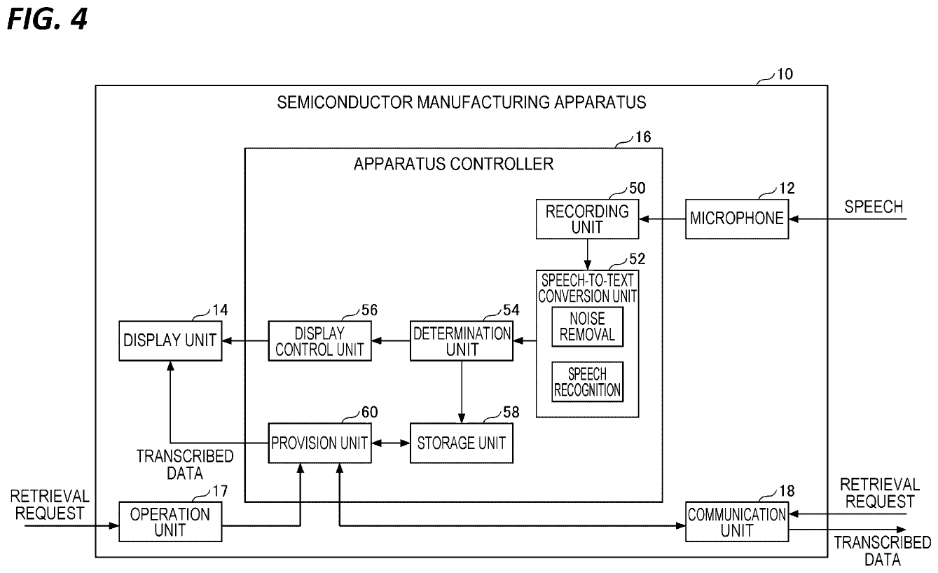

The support system 1 according to the present embodiment implements various functions illustrated in FIG. 4 by executing programs using the computer 500 illustrated in FIG. 2.

### <Functional Configuration>

FIG. 4 is a functional block diagram illustrating an example of the semiconductor manufacturing apparatus 10 according to the present embodiment. The functional block diagram of FIG. 4 omits components that are not necessary for the description of the present embodiment.

The semiconductor manufacturing apparatus 10 illustrated in FIG. 4 includes the microphone 12, the display unit 14, the apparatus controller 16, an operation unit 17, and a communication unit 18. The apparatus controller 16 illustrated in FIG. 4 executes a program for the apparatus controller 16, thereby implementing a recording unit 50, a speech-to-text conversion unit 52, a determination unit 54, a display control unit 56, and a provision unit 60.

The microphone 12 collects speech uttered by the first worker and outputs an audio signal of the first worker's speech to the apparatus controller 16. For example, the microphone 12 may be provided at a position where it is capable of capturing conversations and vocalizations around the semiconductor manufacturing apparatus 10, so as to collect the first worker's speech.

The recording unit 50 of the apparatus controller 16 receives the audio signal from the microphone 12 and records the content spoken by the first worker.

The speech-to-text conversion unit 52 performs processing to convert the recorded data into text. The speech-to-text conversion unit 52 uses a mathematical model, trained through a machine learning algorithm for noise removal and speech recognition, to remove noise from and recognize speech in the recorded data. The term “machine learning algorithm” refers to a data processing method and parameter optimization method that describe how to train a mathematical model using machine learning.

For example, in the present embodiment, by supervised learning using environmental sounds that occur inside the cleanroom 2, a mathematical model (machine learning model) that effectively removes cleanroom-specific environmental noise from the recorded data may be generated. Further, in the present embodiment, by supervised learning using the content spoken by the workers inside the cleanroom 2, a mathematical model that accurately performs speech recognition (including transcription) of the content spoken by the first worker inside the cleanroom 2 may be generated. Since the first worker who speaks inside the cleanroom 2 is generally limited to an expert in the semiconductor industry, the accuracy of speech recognition and transcription may be improved by supervised learning using semiconductor industry-specific technical nouns.

For example, supervised learning used to convert recorded data into text is conducted using annotated training data including elements illustrated in the following table. The annotation elements may include, for example, speech segment, speech content, speaker characteristics, frequency, emotion, and accent, which may be detected and used for training.

TABLE 1

| Annotation | Content |
|---|---|
| Speech segment detection | To clarify information on speech start and end times (structure |
| | of audio data) |
| Speech content detection | To convert speech content in audio data into text on a per- |
| | sentence basis and identify language or dialect used |
| Speaker (industry | To enable speaker identification or semiconductor industry- |
| professional) characteristics | specific noun identification |
| detection | |
| Frequency detection | To learn and predict frequently used words because users are |
| | limited to engineers |
| Emotion detection | To identify emotional state information from variation in vocal |
| | intensity |
| Accent detection | To improve accuracy of word recognition or word |
| | segmentation |

Speech segment detection is to clarify information on the speech start and end times (the structure of audio data). Further, speech content detection is to convert the speech content in the audio data into text on a per-sentence basis and identify the language or dialect used. Further, speaker characteristics detection is to enable speaker identification or semiconductor industry-specific noun identification. Further, frequency detection is to learn and predict frequently used words because the workers are limited to semiconductor engineers and other specialized personnel. Further, accent detection is to improve the accuracy of word recognition or word segmentation.

The determination unit 54 determines which semiconductor manufacturing apparatus 10 the speech content transcribed by the speech-to-text conversion unit 52 pertains to. There are cases where a plurality of semiconductor manufacturing apparatuses 10 are arranged inside the cleanroom 2.

To determine which semiconductor manufacturing apparatus 10 the speech content pertains to, for example, a unique name or identifier of the semiconductor manufacturing apparatus 10 may be included in the content spoken by the first worker. The determination unit 54 determines the semiconductor manufacturing apparatus corresponding to the speech content based on the unique name or identifier of the semiconductor manufacturing apparatus 10 included in the transcribed data. Further, since each semiconductor manufacturing apparatus 10 is equipped with the microphone 12, the determination unit 54 may also determine that the first worker's speech captured by the own microphone 12 thereof is content spoken with respect to itself.

The display control unit 56 causes the display unit 14 viewable by the second worker to display the transcribed data from the speech-to-text conversion unit 52. The display control unit 56 may also cause the display unit 14 viewable by the second worker to display only a part of the transcribed data from the speech-to-text conversion unit 52 that has been determined by the determination unit 54 to pertain to itself.

In the present embodiment, since the content of the first worker's speech is transcribed and displayed as text on the display unit 14, the second worker may accurately recognize the content of the first worker's speech even in the noisy environment of the cleanroom 2, where it is otherwise difficult to hear clearly.

In FIG. 4, a display device viewable by the second worker is illustrated as the display unit 14 of the semiconductor manufacturing apparatus 10, but it may alternatively be the display unit 22 of the terminal device 20 or the display unit 32 of the wearable device 30.

A storage unit 58 stores the data transcribed by the speech-to-text conversion unit 52. Further, the storage unit 58 may also store only a part of the transcribed data from the speech-to-text conversion unit 52 that has been determined by the determination unit 54 to pertain to itself. The storage unit 58 may be implemented using another device capable of communicating with the semiconductor manufacturing apparatus 10, or via cloud storage.

The provision unit 60 provides the transcribed data stored in the storage unit 58 to a retrieval request source in response to a transcribed data retrieval request. FIG. 4 illustrates an example in which the retrieval request originates from a worker who operates the operation unit 17 of the semiconductor manufacturing apparatus 10, or from a worker who operates the terminal device 20 or similar device capable of data communicating with the semiconductor manufacturing apparatus 10.

The operation unit 17 receives a transcribed data retrieval request from the worker and notifies the provision unit 60 of the retrieval request. The provision unit 60 causes the display unit 14 to display the transcribed data stored in the storage unit 58 in response to the retrieval request notified by the operation unit 17.

The communication unit 18 receives a transcribed data retrieval request from the worker who operates the terminal device 20 or similar device capable of data communicating with the semiconductor manufacturing apparatus 10, and notifies the provision unit 60 of the retrieval request. The provision unit 60 transmits the transcribed data stored in the storage unit 58 to the communication unit 18 in response to the retrieval request notified from the communication unit 18. The communication unit 18 then transmits the transcribed data to the terminal device 20 or similar device of the retrieval request source, and causes the display unit 22 of the terminal device 20 to display the transcribed data stored in the storage unit 58.

In the present embodiment, by storing the transcribed data in the storage unit 58, the content spoken by the worker who operated the semiconductor manufacturing apparatus 10 may be confirmed later. In the present embodiment, the ability to later confirm the content spoken by the worker who operated the semiconductor manufacturing apparatus 10 enables visualization of the work, which may offer benefits for verifying work content and conducting risk analysis in the event of an issue.

### <Processing>

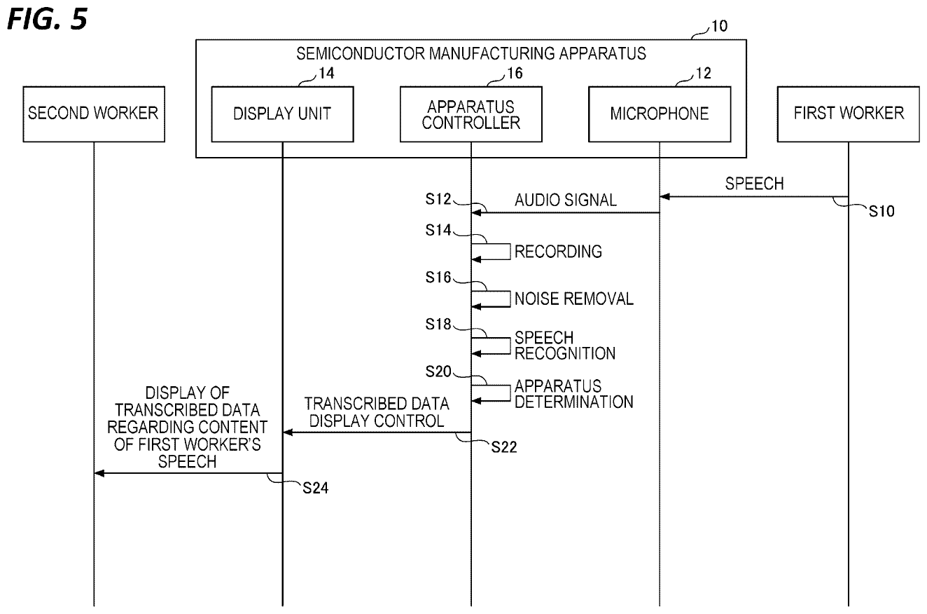

The following describes an example in which a display device viewable by the second worker is the display unit 14 of the semiconductor manufacturing apparatus 10. A display device viewable by the second worker may alternatively be the display unit 22 of the terminal device 20 or the display unit 32 of the wearable device 30. The semiconductor manufacturing apparatus 10 according to the present embodiment executes processing, for example, according to the procedure illustrated in FIG. 5. FIG. 5 is a sequence diagram illustrating an example of processing performed by the semiconductor manufacturing apparatus 10 according to the present embodiment.

In step S10, the first worker, who performs work on the semiconductor manufacturing apparatus 10, speaks the content intended to be communicated to the second worker. The first worker who performs work on the semiconductor manufacturing apparatus 10 may incorporate a unique name or identifier of the semiconductor manufacturing apparatus 10 into the spoken content.

In step S12, the microphone 12 collects speech uttered by the first worker and outputs an audio signal of the first worker's speech to the apparatus controller 16. In step S14, the apparatus controller 16 receives the audio signal of the first worker's speech from the microphone 12, and records the content spoken by the first worker.

In step S16, the apparatus controller 16 performs noise removal on the recorded data using a mathematical model trained for noise removal through a machine learning algorithm.

In step S18, the apparatus controller 16 performs speech recognition on the recorded data using a mathematical model, trained for speech recognition through a machine learning algorithm, thereby transcribing the content spoken by the first worker.

In step S20, the apparatus controller 16 determines which semiconductor manufacturing apparatus 10 the transcribed content (i.e., the transcribed content spoken by the first worker) pertains to.

In step S22, the apparatus controller 16 causes the display unit 14 viewable by the second worker to display the transcribed content of the first worker's speech.

In step S24, the second worker may view the transcribed speech content of the first worker displayed on the display unit 14 of the semiconductor manufacturing apparatus 10. Accordingly, the second worker may accurately understand the content of the first worker's speech by reading the transcribed speech content even in the noisy environment of the cleanroom 2, where it is otherwise difficult to hear clearly.

In this way, since the second worker may accurately understand the content of the first worker's speech, the present embodiment is effective in preventing accidents resulting from insufficient communication between the first and second workers, such as electric shock incidents, contact accidents due to mechanical operations, or unintended shaft-down incidents.

### OTHER EMBODIMENTS

The foregoing described an example in which the first worker communicates with the second worker by converting the content spoken by the first worker into text and displaying it on a display device viewable by the second worker. In addition to this, the semiconductor manufacturing apparatus 10 according to the present embodiment may also convert the content spoken by the second worker into text and display it on a display device viewable by the first worker. The semiconductor manufacturing apparatus 10 may thus facilitate bidirectional communication between the first and second workers.

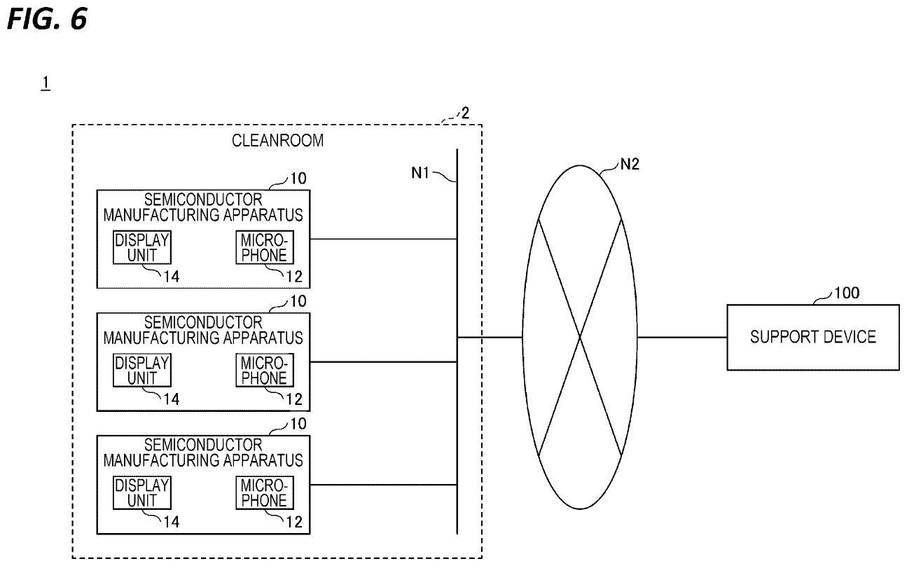

Further, at least part of processing performed by the apparatus controller 16 of the semiconductor manufacturing apparatus 10 described above may be performed by an apparatus other than the semiconductor manufacturing apparatus 10. FIG. 6 is a configuration diagram illustrating an example of the support system 1 according to the present embodiment. The support system 1 illustrated in FIG. 6 includes a plurality of semiconductor manufacturing apparatuses 10 arranged inside the cleanroom 2, and a support device 100. The plurality of semiconductor manufacturing apparatuses 10 and the support device 100 are connected to each other for data communication via networks N1 and N2 such as the Internet or a LAN.

The support device 100 performs at least part of processing performed by the apparatus controller 16 of the semiconductor manufacturing apparatus 10 described above. For example, the support device 100 receives audio data of speech spoken by workers from the semiconductor manufacturing apparatuses 10 inside the cleanroom 2.

The support device 100 converts received audio data into text using a mathematical model, trained for noise removal and/or speech recognition through a machine learning algorithm, and then, returns it to either the semiconductor manufacturing apparatus 10 from which the audio data originated, or the semiconductor manufacturing apparatus 10 determined by the determination unit 54.

Since the support system 1 illustrated in FIG. 6 is capable of receiving audio data of worker's speech from the plurality of semiconductor manufacturing apparatuses 10 inside the cleanroom 2, it enables the use of a mathematical model, trained through a machine learning algorithm, for performing noise removal or speech recognition on the content spoken by the workers inside the cleanroom 2.

A mathematical model, trained using the audio data collected inside the cleanroom 2 through a machine learning algorithm, may accurately remove noise from the audio data collected in that cleanroom 2. Further, a mathematical model, trained using the audio data of worker's speech inside the cleanroom 2 through a machine learning algorithm, may accurately perform speech recognition and transcription on the audio data spoken by the workers inside the cleanroom 2.

It goes without saying that the support system 1 and the semiconductor manufacturing apparatus 10 of the present disclosure are not limited to the illustrated configuration, and various system configurations may be employed depending on the intended use or purpose. The semiconductor manufacturing apparatus 10 of the present disclosure may be applied to any of a single-wafer-type apparatus that processes substrates one by one, as well as a batch-type apparatus or a semi-batch-type apparatus that processes multiple substrates at once.

According to the present disclosure, it is possible to provide a technique for supporting communication between multiple workers who perform work on a semiconductor manufacturing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A semiconductor manufacturing apparatus comprising:
recording circuitry configured to record content spoken by a first worker;
speech-to-text conversion circuitry configured to convert the content recorded by the recording circuitry, into text; and
display control circuitry configured to cause the text to be displaced on a display device viewable by a second worker.

2. The semiconductor manufacturing apparatus according to claim 1, wherein the speech-to-text conversion circuitry performs noise removal and speech recognition on the content recorded by the recording circuitry, using a mathematical model trained by a machine learning algorithm for noise removal and speech recognition.

3. The semiconductor manufacturing apparatus according to claim 1, further comprising:
determination circuitry configured to determine which semiconductor manufacturing apparatus the text corresponds to.

4. The semiconductor manufacturing apparatus according to claim 1, wherein the display control circuitry cause the text to be displayed on a display of the semiconductor manufacturing apparatus, a display of a terminal device possessed by the second worker, or a display of a wearable device worn by the second worker.

5. The semiconductor manufacturing apparatus according to claim 1, further comprising:
storage circuitry configured to store the text; and
provision circuitry configured to provide the text stored in the storage circuitry to a retrieval request source in response to a retrieval request for the text.

6. The semiconductor manufacturing apparatus according to claim 1, wherein a plurality of semiconductor manufacturing apparatuses is arranged inside a cleanroom.

7. A method for supporting work using a semiconductor manufacturing apparatus, the method comprising:
recording content spoken by a first worker;
converting the content into text; and
displaying the text on a display device viewable by a second worker.
